(19) United States
(12) Patent Application Publication
(10) Pub. No.: US 2007/0132475 A1
(43) Pub. Date: Jun. 14, 2007

(54) Semiconductor device test method and device

(76) Inventors: Ana Maria Sa Carneiro Leao, Porto (PT); Marc Mueldner, Muenchen (DE); Mehdi Rostami, Covilha (PT); Michael Schittenhelm, Poing (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/605,558

(22) Filed: Nov. 29, 2006

(30) Foreign Application Priority Data
Nov. 29, 2005 (DE) 10 2005 056 930.7

(51) Int. Cl. G01R 31/26

(52) U.S. Cl. 324/765

(57) ABSTRACT

A semiconductor device test method for testing a semiconductor device is disclosed. In one embodiment, for transmitting control information to a device that is connected between a test device and the semiconductor device, a non-standard-compliant signal is sent to the device. Furthermore, the invention relates to a semiconductor device test device and a device that is, for performing a semiconductor device test method, connected between a test device and a semiconductor device to be tested.

### CROSS-REFERENCE TO RELATED APPLICATIONS

This Utility Patent Application claims priority to German Patent Application No. DE 10 2005 056 930.7 filed on Nov. 29, 2005, which is incorporated herein by reference.

### FIELD OF INVENTION

The invention relates to a semiconductor device test method, a semiconductor device test device, and to a device connected between a test device and a semiconductor device to be tested for performing a semiconductor device test method.

### BACKGROUND

Semiconductor devices, e.g., corresponding, integrated (analog or digital) computing circuits, semiconductor memory devices such as functional memory devices (PLAs, PALs, etc.) and table memory devices (e.g., ROMs or RAMs, in particular SRAMs and DRAMs), etc. are subject to comprehensive tests in the course of their manufacturing process and after manufacturing.

For the common manufacturing of a plurality of (in general identical) semiconductor devices, a so-called wafer (i.e., a thin disc consisting of monocrystalline silicon) is used. The wafer processed appropriately (e.g., successively subject to a plurality of coating, exposure, etching, diffusion, and implantation processes, etc.), and subsequently e.g., sawn apart (or e.g., scratched and broken), so that the individual devices are then available.

During the manufacturing of semiconductor devices (e.g., of DRAMS (Dynamic Random Access Memories or dynamic write-read memories, respectively), in particular of DDR-DRAMs (Double Data Rate—DRAMs)), the (semi-finished) devices (that are still positioned on the wafer) may even before all the desired, above-mentioned processing was performed at the wafer—(i.e., already in a semi-finished state of the semiconductor devices) be subject to appropriate test methods (e.g., so-called kerf measurements at the wafer kerf) at one or a plurality of test stations by means of one or a plurality of test devices.

After the finishing of the semiconductor devices (i.e., after the performing of all the above-mentioned wafer processing), the semiconductor devices are subject to further test methods at one or a plurality of (further) test stations the finished devices that are still positioned on the wafer may, for instance, be correspondingly tested by means of appropriate (further) test devices (“disc tests”).

Correspondingly, one or a plurality or further tests may be performed (at appropriate further test stations, using appropriate, further test devices) e.g., after the incorporation of the semiconductor devices in the corresponding semiconductor device packages, and/or e.g., after the incorporation of the semiconductor device package (along with the respective semiconductor devices incorporated therein) in corresponding electronic modules (so-called “module tests”).

When testing semiconductor devices, so-called “DC tests” and/or so-called “AC tests” may, for instance, be used as test methods (e.g., with the above-mentioned disc tests, module tests, etc.).

In a DC test, a voltage (or current) of particular especially constant intensity may, for instance, be applied to a corresponding pin of a semiconductor device to be tested or DUT (DUT=Device Under Test), respectively, and then the intensity of resulting currents (or voltages) may be measured in particular it may be examined whether these currents (or voltages) range within predetermined, desired threshold values.

Contrary to this, in an AC test, voltages (or currents) varying in intensity may, for instance, be applied to corresponding pins of a semiconductor device, in particular corresponding test pattern signals by means of which appropriate function tests may be performed at the respective semiconductor device.

For instance after sending a corresponding WRITE signal by the respective test device one or a plurality of test data bits may be stored in the semiconductor device, and then after sending a corresponding READ signal be read out again; subsequently, it may be examined whether the data bits that have been read out concur with those that had been stored before.

By means of the above-mentioned test methods it is possible to identify and then sort out (or partially also repair) defective semiconductor devices or modules, respectively, and/or corresponding to the test results achieved to correspondingly modify or adjust optimally, respectively, the process parameters used during the manufacturing of the devices, etc.

When performing the above mentioned test methods, a means increasing or enlarging the functionality of the test device may be connected between the respective test device (in particular the respective ATE (ATE=Automated Test Equipment)) and the respective semiconductor device to be tested or the DUT, respectively, e.g., an AED (AED=Active Electronic Device) provided externally of the test device.

The AED may use a higher-frequency clock transmitted to the respective semiconductor device to be tested than the respective ATE. The operability of the semiconductor device may then be tested for higher transmission rates than without AED.

ATEs each include only a restricted number of test channels. By means of these for cost reasons as many semiconductor devices as possible are to be tested simultaneously in parallel.

A part of the test channels is used for controlling the above mentioned AEDs that are connected between the respective ATE and the respective DUTs. This results in an undesired increase of the total amount of test channels required for testing a semiconductor device (and thus correspondingly to a reduced number of semiconductor devices that can be tested simultaneously in parallel).

For these and other reasons there is a need for the present invention.

### SUMMARY

One or more embodiments provide a method for testing a semiconductor device, a semiconductor device test device, and a device. In one embodiment, the method includes connecting a device between a test device and the semiconductor device and transmitting control information to the device by sending a non-standard-compliant signal to the device.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 schematically illustrates representation of a conventional test system with AED.

FIG. 2 schematically illustrates representation of a test system in accordance with an embodiment of the present invention.

FIG. 3 schematically illustrates representation of a first example of a standard-compliant signal used with the test system of FIG. 2, and of a non-standard-compliant signal that may additionally be used as DQS control signal;

FIG. 4 schematically illustrates representation of a second example of a standard-compliant signal used with the test system of FIG. 2, and of a non-standard-compliant signal that may additionally be used as DQS control signal.

FIG. 5 schematically illustrates representation of a further example of a standard-compliant signal used with the test system of FIG. 2, and of a non-standard-compliant signal that may additionally be used as DQS control signal.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a novel semiconductor device test method, a novel semiconductor device test device, and a novel device connected between a test device and a semiconductor device to be tested for performing a semiconductor device test method, in particular a method, a test device, and a device by which the number of test channels required for testing a semiconductor device can be reduced.

In accordance with one embodiment of the invention there is provided a semiconductor device test method for testing a semiconductor device, wherein, for transmitting information, in particular control information, to a device connected between a test device and the semiconductor device, a non-standard-compliant signal is sent to the device.

The control information or the non-standard-compliant signal, respectively, may indicate that a pin, in particular a DQS pin of the device is to be placed in a highly resistive state.

The (non-standard-compliant) signal used for transmitting the control information may be transmitted via the same test channel as a corresponding standard compliant signal used for transmitting further information (control, address, or reference data information) and not, as in prior art, via a separate, additional test channel. Thus, the total number of test channels required for testing a semiconductor device may be reduced, or with an equal number of test channels a larger amount of semiconductor devices may be tested simultaneously in parallel with one test device, respectively.

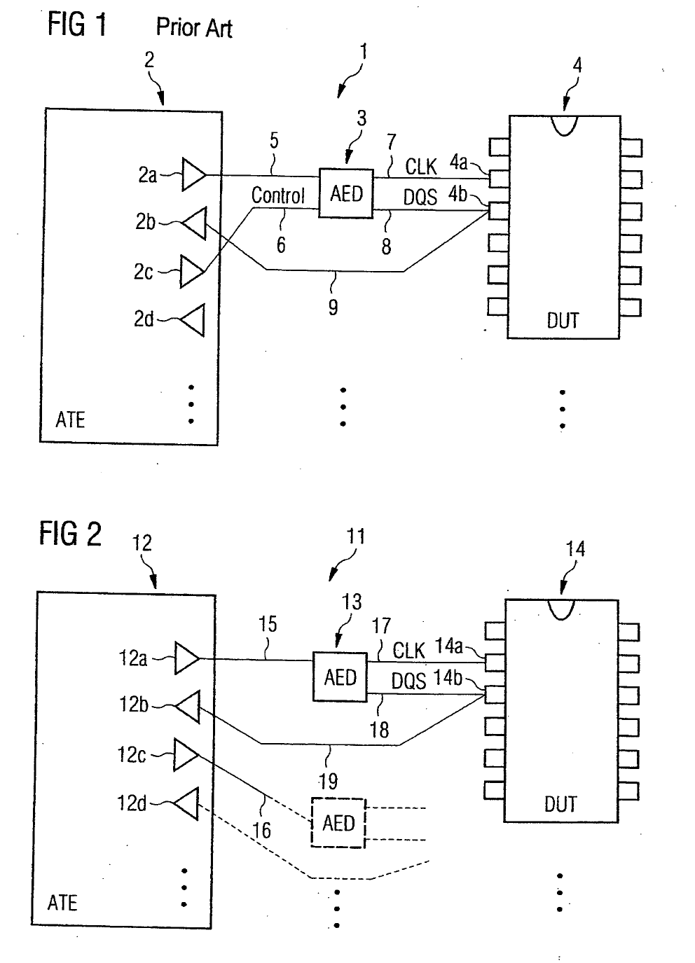

FIG. 1 illustrates a schematic representation of a conventional AED test system 1.

As results from FIG. 1, the test system 1 comprises a test device 2 (here: an appropriate ATE (ATE=Automated Test Equipment)) by means of which a plurality of semiconductor devices 4 (DUT=Device Under Test) can be tested simultaneously in parallel.

The semiconductor devices 4 may, for instance, be integrated (analog or digital) computing circuits arranged in appropriate semiconductor device packages, and/or semiconductor memory devices such as functional memory devices (PLAs, PALs, etc.) and table memory devices (e.g., ROMs or RAMs, in particular SRAMs and DRAMs), in particular DDR-DRAMs.

To increase or enlarge the functionality of the test device 2, corresponding means 3 provided externally of the test device 2 are connected between the test device 2 and the semiconductor devices 4 to be tested, in particular corresponding AEDs (AED=Active Electronic Device) provided on one or a plurality of separate integrated circuits or comprising one or several separate integrated circuits or ASICS, respectively.

The test device 2 includes a limited number of test channels which are via corresponding signal drivers 2a, 2c or signal receivers 2b, 2d connected to corresponding external test lines 5, 6, 9. By means of the available test channels for cost reasons as many semiconductor devices 4 as possible are to be tested simultaneously in parallel.

For instance, one or a plurality of test data bits that are sent out at corresponding (not illustrated) DATA test channels or DATA test lines connected therewith, respectively, can be stored in the semiconductor devices 4 by the test device 2 by sending out a corresponding WRITE signal at a (not illustrated) COMMAND test channel or at a COMMAND test line connected therewith, respectively (namely respectively at addresses specified by address bits sent at corresponding (not illustrated) ADDRESS test channels or ADDRESS test lines connected therewith, respectively). Subsequently, the test device 2 may, by sending out a corresponding READ signal and the corresponding address bits, read out the test data bits from the semiconductor devices 4 again.

Next, it may be examined whether the data bits read out concur with those that had been stored before.

A part of the above mentioned test channels or of the test lines connected therewith, respectively, provided by the test device 2 is other than, for instance, the above-mentioned DATA, ADDRESS, and COMMAND test channels or lines not directly connected with the semiconductor devices 4, but by interconnection of the AED 3 (e.g., a clock test channel or a clock test line 5 connected therewith, respectively, and/or a DQS control test channel or a DQS control test line 6 connected therewith, respectively, etc.).

The AED 3 may use a higher-frequency clock CLK transmitted to the respective semiconductor device 4 to be tested or the CLK pin 4a thereof, respectively, via a corresponding clock test line 7 than the test device 2. The operability of the semiconductor devices 4 may then be tested for correspondingly higher transmission rates than without AED 3.

The validity of the above mentioned test data bits sent out after the WRITE signal via the above-mentioned DATA test channels or the DATA test lines connected therewith, respectively, by the test device 2 is indicated to the semiconductor devices 4 by means of a data strobe signal (DQS signal) transmitted by the AED 3 via a test line 8 connected with a corresponding DQS pin 4b of the semiconductor devices 4 more exactly in that corresponding signal drivers of the AED 3 which are connected with the DQS test line 8 take care that the signal present at the DQS test line 8 changes its state (e.g., from “logic high” to “logic low” (or vice versa)).

Correspondingly conversely, the validity of the above-mentioned data bits sent out after the READ signal via the above-mentioned DATA test channels or the DATA test lines connected therewith, respectively, by the respective semiconductor device 4 is indicated to the test device 2 by means of a data strobe signal (DQS signal) transmitted by the respective semiconductor device 4 also via the above mentioned DQS pin 4b and a test line 9 connected therewith and with the test device 2 more exactly in that corresponding signal drivers of the respective semiconductor device 4 which are connected with the DQS pin 4b and the DQS test line 9 take care that the signal present at the test line 9 changes its state (e.g. from “logic high” to “logic low” (or vice versa)).

Since the DQS pin 4b as results from the explanations above is, except with the DQS test line 9 that is connected with the test device 2, additionally connected with the DQS test line 8 that is connected with the AED 3, it has to be ensured that, at a point in time at which the signal drivers of the respective semiconductor device 4 output the corresponding data strobe signal (DQS signal) via the DQS pin 4b or the DQS test line 9, respectively, the signal drivers of the AED 3 which are connected with the DQS test line 8 or the corresponding pin of the AED 3 which is connected with the DQS test line 8, respectively, are placed in a highly resistive state.

To this end, in the conventional test system 1 illustrated in FIG. 1, the test device 2 sends, via the above mentioned separate DQS control test line 6, a corresponding DQS indication or DQS control signal to the AED 3 (and in reaction thereto, the signal drivers of the AED 3 which are connected with the DQS test line 8 or the corresponding pin of the AED 3 which is connected with the DQS test line 8, respectively, are placed in a highly resistive state).

A part of the test channels of the test device 2 e.g., the test channel connected with the above-mentioned DQS control test line 6 is thus required for controlling the above-mentioned AED 3 that is connected between the test device 2 and the respective semiconductor devices 4. This results in an undesired increase of the total number of test channels required for testing a semiconductor device 4 (and hence correspondingly to a reduced number of semiconductor devices that can be tested simultaneously in parallel).

FIG. 2 illustrates a schematic representation of a test system 11 according to an embodiment of the invention.

As results from FIG. 2, the test system 11 includes correspondingly similar as conventional test systems a test device 12 (here: an appropriate ATE (ATE=Automated Test Equipment)) by means of which a plurality of semiconductor devices 14 (DUT=Device Under Test) can be tested simultaneously in parallel.

The semiconductor devices 14 may, for instance, be integrated (analog or digital) computing circuits arranged in appropriate semiconductor device packages, and/or semiconductor memory devices such as functional memory devices (PLAs, PALs, etc.) and table memory devices (e.g., ROMs or RAMs, in particular SRAMs and DRAMs), in particular DDR-DRAMs.

To increase or enlarge the functionality of the test device 12, corresponding means 13 provided externally of the test device 12 are connected between the test device 12 and the semiconductor devices 14 to be tested, in particular corresponding AEDs (AED=Active Electronic Device) provided on one or a plurality of separate integrated circuits or comprising one or several separate integrated circuits or ASICS, respectively.

The test device 12 comprises a limited number of test channels which are via corresponding signal drivers 12a, 12c or signal receivers 12b, 12d connected to corresponding external test lines 15, 16, 19. By means of the available test channels for cost reasons as many semiconductor devices 14 as possible are to be tested simultaneously in parallel.

For instance, one or a plurality of test data bits that are sent out at corresponding (not illustrated) DATA test channels or at DATA test lines connected therewith, respectively, can be stored in the semiconductor devices 14 by the test device 12 by sending out a corresponding WRITE signal at a (not illustrated) COMMAND test channel or at a COMMAND test line connected therewith, respectively (namely respectively at addresses specified by address bits sent at corresponding (not illustrated) ADDRESS test channels or ADDRESS test lines connected therewith, respectively).

Subsequently in particular directly thereafter, the test device 12 may, by sending out a corresponding READ signal and the corresponding address bits, read out the test data bits from the semiconductor devices 14 again.

Next, it may be examined whether the data bits read out concur with those that had been stored before (no error case), or not (error case). Thus it is possible to identify and sort out (or possibly also repair) defective semiconductor devices 14, and/or corresponding to the test results achieved to correspondingly modify or adjust optimally, respectively, the process parameters used during the manufacturing of the semiconductor devices 14, etc.

The respective test data bits to be stored with the above described exemplary test in the semiconductor devices 14 (and to be read out subsequently again) may, for instance, be generated by a pseudo random bit generator provided on the test device 12.

A part of the above-mentioned test channels or of the test lines connected therewith, respectively, provided by the test device 12 is other than, for instance, the above-mentioned DATA, ADDRESS, and COMMAND test channels or lines not directly connected with the semiconductor devices 14, but by interconnection of the AED 13 (e.g., a clock test channel or a clock test line 15 connected therewith, respectively, etc.).

Alternatively or additionally, a part or all of the above-mentioned test channels or test lines which are directly connected with the semiconductor devices 14, e.g., the above-mentioned DATA, ADDRESS, and COMMAND test channels or test lines, may additionally also be connected with the AED 13.

The AED 13 may use a higher-frequency clock CLK transmitted to the respective semiconductor device 14 to be tested or the CLK pin 14a thereof, respectively, via a corresponding clock test line 17 than the test device 12 (e.g., clock CLK of higher frequency than the clock provided by the test device 12 at the clock test line 15).

The operability of the semiconductor devices 14 may then be tested for correspondingly higher transmission rates than without AED 13.

The validity of the above-mentioned test data bits sent out after the WRITE signal via the above mentioned DATA test channels or the DATA test lines connected therewith, respectively, by the test device 12 is indicated to the semiconductor devices 14 by means of a data strobe signal (DQS signal) transmitted by the AED 13 via a test line 18 connected with a corresponding DQS pin 14b of the semiconductor devices 14 more exactly in that corresponding signal drivers of the AED 13 which are connected with the DQS test line 18 take care that the signal present at the DQS test line 18 in the case of validity of the test data bits to be read in changes its state (e.g., from “logic high” to “logic low” (or vice versa)).

Correspondingly conversely, the validity of the above mentioned data bits sent out after the READ signal via the above mentioned DATA test channels or the DATA test lines connected therewith, respectively, by the respective semiconductor device 14 is indicated to the test device 12 by means of a data strobe signal (DQS signal) transmitted by the respective semiconductor device 14 also via the above-mentioned DQS pin 14b and a test line 19 connected therewith and with the test device 12 more exactly in that corresponding signal drivers of the respective semiconductor device 14 which are connected with the DQS pin 14b and the DQS test line 19 take care that the signal present at the test line 19 in the case of validity of the test data bits read out changes its state (e.g., from “logic high” to “logic low” (or vice versa)).

Since the DQS pin 14b as results from the explanations above is, except with the DQS test line 19 that is connected with the test device 12, additionally connected with the DQS test line 18 that is connected with the AED 13, it has to be ensured that, at a point in time at which the signal drivers of the respective semiconductor device 14 output the corresponding data strobe signal (DQS signal) via the DQS pin 14b or the DQS test line 19, respectively, the signal drivers of the AED 13 which are connected with the DQS test line 18 or the corresponding pin of the AED 13 which is connected with the DQS test line 18, respectively, are placed in a highly resistive state.

To indicate to the AED 13 that the signal drivers of the AED 13 which are connected with the DQS test line 18 or the corresponding pin of the AED 13 which is connected with the DQS test line 18 are to be placed in a highly resistive state, in the present embodiment other than conventionally, and as will be described in more detail in the following the test device 12 need not send any (separate) DQS strobe or DQS control signal via a separate test channel or a separate test line, respectively (cf. e.g., the separate test line 6 illustrated in FIG. 1).

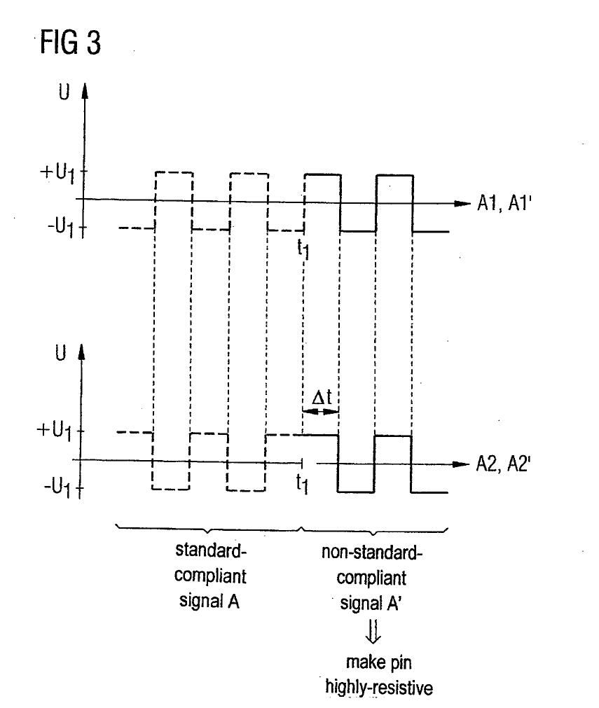

Instead as is, for instance, illustrated in FIG. 3 via a test line that is present anyway, but usually employed for some other purpose (e.g., the test line 15) or a test channel that is present anyway, but usually employed for some other purpose, a non-standard-compliant signal A′ is transmitted instead of a standard-compliant signal A, and by the deviation from the standard, via the corresponding test line 15, the (additional) information interpreted by the AED 13 as “DQS strobe signal” or “DQS control signal”, respectively, is transmitted, indicating that the signal drivers of the AED 13 which are connected with the DQS test line 18 or the corresponding pin of the AED 13 which is connected with the DQS test line 18—are to be placed in a highly resistive state.

As results from FIG. 3, the non-standard-compliant signal A′ that is interpreted as “DQS strobe signal” or “DQS control signal” by the AED 13 may differ from the standard-compliant signal A with respect to timing.

For instance, the standard compliant signal A (more exactly: A2) may first of all be sent out, and from a point in time ti on the non-standard-compliant signal A′ (more exactly: A2′) that is phase-shifted vis-a-vis the standard compliant signal A (more exactly: A2) by a duration At.

As soon as the AED 13 has determined that the non-compliant signal A′ (“DQS strobe signal” or “DQS control signal”) was transmitted via the corresponding test line 15 instead of the standard-compliant signal A i.e., approximately at the point in time t₁, the AED 13 places the corresponding pin of the AED 13 which is connected with the DQS test line 18 in a highly resistive state. Alternatively, the corresponding (DQS) pin may not instantly be placed in a highly resistive state by the AED 13, but deliberately somewhat delayed, i.e., a predetermined duration after the determination that the non-standard-compliant signal A′ was transmitted via the corresponding test line 15 instead of the standard compliant signal A.

As illustrated in FIG. 3, the standard compliant signal A may include two partial signals A1, A2 that are transmitted via a corresponding line pair, that are sent in antiphase, and that are respectively inverse to each other (wherein, whenever the first partial signal A1 changes its state e.g., from “logic high” to “logic low”, the second partial signal A2 inversely changes its state e.g., from “logic low” to “logic high”, and whenever the first partial signal A1 changes its state e.g., from “logic low” to “logic high”, the second partial signal A1 inversely changes its state from “logic high” to “logic low”).

Contrary to this, the non-standard-compliant signal A′ may include two partial signals A1′, A2′ that are transmitted via the corresponding line pair in an equiphase manner (wherein, whenever the first partial signal A1′ changes its state e.g., from “logic high” to “logic low”, the second partial signal A2′ also changes its state e.g., from “logic high” to “logic low”, and whenever the first partial signal A1′ changes its state e.g., from “logic low” to “logic high”, the second partial signal A2′ also changes its state from “logic low” to “logic high”).

Alternatively other than illustrated in FIG. 3, the standard compliant signal A may, for instance, also include two partial signals A1, A2 transmitted via a corresponding line pair and phase-shifted by 90°.

Contrary to this, the non-standard-compliant signal A′ may include two partial signals A1′, A2′ transmitted via the corresponding line pair e.g. i) in an antiphase manner, or alternatively e.g. ii) in an equiphase manner.

By the deviation form the standard pursuant to i) antiphase transmission of the partial signals A1′, A2′ (instead of transmission phase-shifted by 90°), the corresponding test line 15 may transmit the (additional) information that is interpreted by the AED 13 as “DQS control signal”, indicating that the signal drivers of the AED 13 which are connected with the DQS test line 18 are to be placed in a highly resistive state, and by the deviation from the standard pursuant to ii) equiphase transmission of the partial signals A1′, A2′ (instead of transmission phase-shifted by 90°) a further additional information differing therefrom (or vice versa).

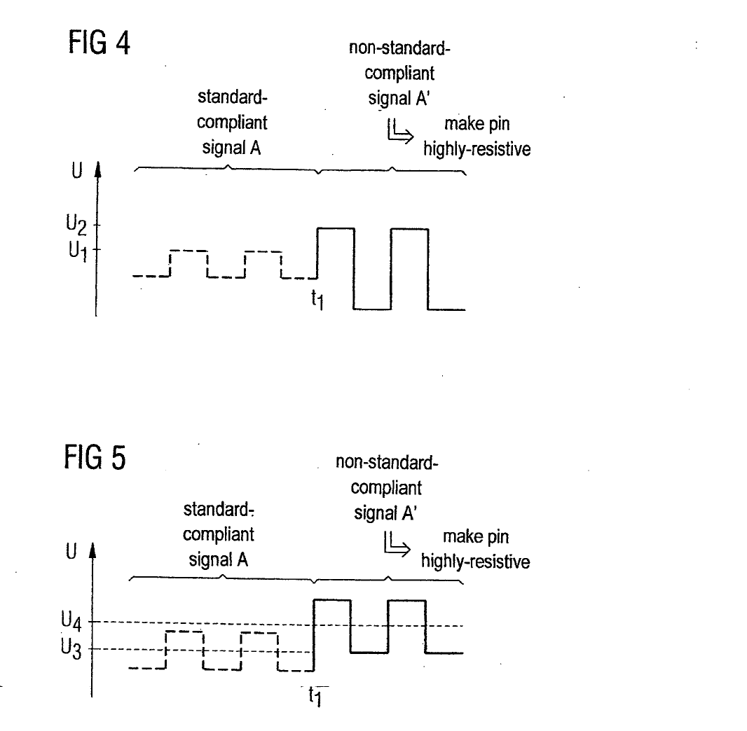

As results from FIG. 4, the non-standard-compliant signal A′ that is interpreted as DQS control signal “by the AED 13 may, alternatively or additionally to the timing, also differ from the standard compliant signal A in any other way, e.g., with respect to the amplitude.

For instance, as is illustrated in FIG. 4, the standard-compliant signal A may include a first (maximum) amplitude U1, and the non-standard-compliant signal A′ sent from the point in time t₁ on—a second (maximum) amplitude U2 differing therefrom (wherein the maximum amplitudes U1 or U2 may be the respective signal amplitudes in the respectively “logic high” (or “logic low”) signal state (and the minimum amplitudes that may be the respective signal amplitudes in the respectively “logic low” (or “logic high”) signal state may be respectively identical or also different for both signals A, A′ (in particular e.g., such that a respectively identical DC value results for both signals A, A′))).

As results from FIG. 5, the non-standard-compliant signal A′ that is interpreted as “DQS control signal” by the AED 13 may, alternatively or additionally to the timing and/or to the amplitude, also differ from the standard compliant signal A in any other way, e.g. with respect to the DC value.

For instance, as is illustrated in FIG. 5, the standard-compliant signal A may comprise a first DC value U3 (i.e., a first average value between the signal amplitudes in the respectively “logic high” and “logic low” signal states), and the non-standard-compliant signal A′ a second, different DC value U4 (i.e., a second average value between the signal amplitudes in the respectively “logic high” and “logic low” signals states which differs from the first average value), etc.

A non-standard-compliant signal A′ that is interpreted as “DQS control signal” by the AED 13 may, for instance, also be generated in that the drivers of the test device 12 which drive the corresponding standard compliant signal A via the corresponding test line (e.g., the test line 15) or a corresponding test device pin that is connected with the corresponding test line (e.g., the test line 15), respectively, are placed in a highly resistive state. The test line 15 is then neither in a state logic high” nor logic low”, but in a high-impedance state differing therefrom. In this state, no current (or a substantially lower current than in the state “logic high” or “logic low”, respectively) flows over the corresponding test line 15, or a temporally constant voltage is present at the test line 15 (or a substantially lower or alternatively, substantially higher voltage than in the state “logic high” or “logic low”), so that the presence of a non-standard-compliant signal A′ may be determined in a simple manner e.g., by an appropriate current or voltage measurement in the AED 13.

For transmitting the respective non-standard-compliant signal A′ that can be interpreted as “DQS control signal” by the deviation from the standard any test line provided between the test device 12 and the AED 13 may, on principle, be used, i.e., instead of the above-mentioned clock test line 15 also any other DATA, ADDRESS, or COMMAND test line (in particular a COMMAND test line via which actually other control data are transmitted than the above-mentioned “DQS control signal”).

As results from FIGS. 3 to 5, the non-standard-compliant signal A′ transmitted via the corresponding test line (e.g., the clock test line 15) may in addition to the above-mentioned given information content that can, by the deviation from the standard, be interpreted as “DQS strobe signal” additionally also includes the information content that is “conventionally” accorded to the corresponding standard-compliant signal (control, address, or reference data information). In a first variant of the invention, the corresponding, non-standard-compliant signal A′ is nevertheless always interpreted by the AED 13 exclusively as DQS strobe signal or DQS control signal, respectively, and as a signal that does not comprise any exceeding information content. In a second variant, the corresponding, non-compliant signal A′ is instead in parallel interpreted by the AED 13 as DQS strobe signal or DQS control signal, respectively, and as additionally comprising the above-mentioned information content that is “conventionally” accorded to the corresponding standard compliant signal.

Since, in the test system 11 illustrated in FIG. 2 other than conventionally, and as described above, no separate, additional test channel or no separate, additional test line, respectively, is required for transmitting the “DQS strobe signal” or the “DQS control signal”, respectively, the number of test channels that are altogether required for testing a respective semiconductor device 14 may be reduced (or with an equal number of test channels an increased number of semiconductor devices 14 can be tested simultaneously in parallel).

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for testing a semiconductor device comprising:
connecting a device between a test device and the semiconductor device; and
transmitting control information to the device by sending a non-standard-compliant signal to the device.

2. The method according to claim 1 comprising:
defining the control information to indicate that a pin of the device is to be placed in a highly resistive state.

3. The method according to claim 2, comprising:
defining the control information to indicate immediately placing the pin of the device in a highly resistive state.

4. The method according to claim 2, comprising:
defining the control information to indicate placing the pin of the device in a highly resistive state after a predetermined period.

5. The method according to claim 2, comprising:
defining the pin to be a bidirectional pin.

6. The method according to claim 2, comprising:
transmitting via the pin a data strobe signal from the device to the semiconductor device, and/or a data strobe signal from the semiconductor device to the device.

7. The method according to claim 1, comprising:
defining the device to comprise one or a plurality of separate semiconductor devices that are provided externally of the test device.

8. The method according to claim 7, comprising:
defining the device as an AED or Active Electronic Device.

9. The method according to claim 1, comprising:
defining the non-standard-compliant signal to differ from a standard-compliant signal with respect to the points in time of the change of the signal state.

10. The method according to claim 9, comprising:
defining the non-standard-compliant signal to be phase-shifted vis-a-vis the standard-compliant signal.

11. The method according to claim 9, comprising:
defining the standard-compliant signal to comprise two partial signals sent in antiphase, and wherein the non-standard-compliant signal instead comprises two partial signals sent in equiphase.

12. The method according to claim 1, comprising:
defining the non-standard-compliant signal to differ from a standard-compliant signal with respect to the amplitude.

13. The method according to claim 1, comprising:
defining the non-standard-compliant signal to differ from a standard-compliant signal with respect to the voltage reference point.

14. The method according to claim 1, comprising:
placing drivers of the test device driving a corresponding standard-compliant signal, or a corresponding test device pin, respectively, in a highly resistive state for sending the non-standard-compliant signal

15. A semiconductor device test device for testing a semiconductor device comprising:
a test device configured for transmitting control information to a device connected between the test device and the semiconductor device, wherein the control information is sent via a non-standard-compliant signal sent to the device by the test device.

16. The device according to claim 15 comprising:
wherein the control information indicates that a pin of the device is to be placed in a highly resistive state.

17. The device according to claim 16, comprising:
wherein the control information indicates immediately placing the pin of the device in a highly resistive state.

18. The device according to claim 16, comprising:
wherein the control information indicates placing the pin of the device in a highly resistive state after a predetermined period.

19. The device according to claim 16, comprising:
wherein the pin is a bidirectional pin.

20. The device according to claim 16, comprising:
wherein the pin is used to transmit a data strobe signal from the device to the semiconductor device, and/or a data strobe signal from the semiconductor device to the device.

21. The device according to claim 16, comprising:
wherein the non-standard-compliant signal differs from a standard-compliant signal with respect to the points in time of the change of the signal state.

22. The device according to claim 9, comprising:
defining the non-standard-compliant signal to be phase-shifted vis-a-vis the standard-compliant signal.

23. The method according to claim 15, comprising:
wherein the standard-compliant signal comprises two partial signals sent in antiphase, and wherein the non-standard-compliant signal comprises two partial signals sent in equiphase.

24. The method according to claim 15, comprising:
wherein the non-standard-compliant signal differs from a standard-compliant signal with respect to the amplitude.

25. The method according to claim 15, comprising: wherein the non-standard-compliant signal differs from a standard-compliant signal with respect to the voltage reference point.

26. A device used for performing a semiconductor device test method, comprising:
a device configured to be connected between a test device and a semiconductor device to be tested, the device configured and equipped such that, in reaction to a non-standard-compliant signal received, a pin of the device is placed in a highly resistive state.

27. A semiconductor device test device for testing a semiconductor device comprising:
a test device configured for transmitting control information to a device connected between the test device and the semiconductor device; and
means for providing the control information via a non-standard-compliant signal sent to the device by the test device.
